(19) United States
(12) Patent Application Publication
(10) Pub. No.: US 2012/0060922 A1
(43) Pub. Date: Mar. 15, 2012

(54) LAYERED INORGANIC NANOCRYSTAL PHOTOVOLTAIC DEVICES

(75) Inventors: Cyrus Wadia, Berkeley, CA (US); Yue Wu, West lafayette, IN (US); Paul A. Alivisatos, Berkeley, CA (US)

(73) Assignee: The Regents of the University of California, Oakland, CA (US)

(21) Appl. No.: 12/920,260

(22) PCT Filed: Mar. 2, 2009
(86) PCT No.: PCT/US09/35699

§ 371 Date: Nov. 22, 2010

Related U.S. Application Data
(60) Provisional application No. 61/033,369, filed on Mar. 3, 2008.

(51) Int. Cl. H01L 31/0296; H01L 31/18; C01G 3/12; H01L 29/225; H01L 31/04; B82Y 40/00; B82Y 30/00

(52) U.S. Cl. 136/260; 257/201; 438/94; 136/265; 423/561.1; 257/E31.005; 257/E29.097; 977/773; 977/896

(57) ABSTRACT

A non-sintered structure. The non-sintered structure includes a first non-sintered nanocrystal layer, and a second non-sintered nanocrystal layer wherein the first layer and the second layer are configured to interact electronically.

### CROSS-REFERENCES TO RELATED APPLICATIONS

This application is a non-provisional of and claims the benefit of the filing date of U.S. Patent Application No. 61/033,369, filed on Mar. 3, 2008, which is herein incorporated by reference in its entirety for all purposes.

### STATEMENT AS TO RIGHTS TO INVENTIONS MADE UNDER FEDERALLY SPONSORED RESEARCH OR DEVELOPMENT

The invention described and claimed herein was made in part utilizing funds supplied by the U.S. Department of Energy under Contract No. DE-AC02-05CH11231 and by the Department of the Air Force (AFOSRA) under award No. FA9550-06-1-0488. Additional funding was provided by the Environmental Protection Agency and by the Miller Institute for Basic Research in Science of the University of California at Berkeley. The Government has certain rights in this invention.

### BACKGROUND OF THE INVENTION

Embodiments of the invention generally relate to solar cell devices, and, more specifically, to non-sintered inorganic layered nanocrystal photovoltaic cells and methods of their preparation.

Substantial effort has been made to use semiconductor nanostructures as building blocks for photovoltaic devices. Examples include dye-sensitized solar cells, all-inorganic solar cells, and hybrid nanocrystal-polymer composite solar cells, all of which offer advantages when compared with conventional single crystal and thin film solar cells. In many cases, the semiconductor nanostructures that have been employed for solar cells have a relatively large bandgap (≧1.7 eV), leaving a considerable portion of the incident solar energy spectrum unused. To generate photocurrent from low energy photons, small bandgap semiconductor nanostructures are highly desirable.

Current inorganic nanocrystal photovoltaic devices require annealing or sintering at high temperatures, usually more than 200° C. High temperature treatment is expensive; it requires a lot of energy. Such energy expenditure will become more undesirable as time goes on. In addition, substrate and contact materials that can withstand such high temperature treatment must be used. This eliminates the possibility of making such devices on polymer substrates, which could further reduce the cost of production and could introduce new features, such as flexibility to nanocrystal photovoltaic devices. Thus, there are several disadvantages in having to treat photovoltaic devices at high temperatures. In addition, the inorganic materials used in these devices have often used materials that have suboptimal optical properties and environmental and economic attributes.

What is needed is an inorganic nanocrystal photovoltaic device that is efficient over a very large portion of the solar spectrum and that can be fabricated at low temperature.

### BRIEF SUMMARY OF THE INVENTION

Embodiments of the invention are directed to composite materials, methods for making composite materials as well as devices incorporating such composite materials. Other embodiments of the invention are directed to nanocrystals and methods for making nanocrystals.

One embodiment of the invention is directed to a method for forming a non-sintered structure comprising: a first non-sintered nanocrystal layer; and a second non-sintered nanocrystal layer wherein the first layer and the second layer are configured to interact electronically.

Another embodiment of the invention is directed to a solar cell device, comprising: a substrate comprising a first conducting layer; a Cu₂S nanocrystal layer adjacent the first conducting layer of the substrate; a CdS nanocrystal layer adjacent the Cu₂S nanocrystal layer; and a second conducting layer adjacent the CdS nanocrystal layer.

Another embodiment of the invention is directed to a solar cell device, comprising: a flexible substrate having at least one conducting surface; a layer of first inorganic nanocrystals adjacent the conducting surface of the substrate; a layer of second inorganic nanocrystals adjacent the first layer; and a conducting layer adjacent the second layer.

Another embodiment of the invention is directed to a method comprising: forming a first non-sintered nanocrystal layer; and forming a second non-sintered nanocrystal layer wherein the first layer and the second layer are configured to interact electronically.

Another embodiment of the invention is directed to a method for making semiconductor nanocrystals, each semiconductor nanocrystal comprising a first element and a second element, the method comprising: mixing a first precursor comprising the second element and an organic solvent to form a first solution; heating the first solution to a first temperature no higher than 140° C.; injecting a suspension comprising a second precursor comprising the first element into the first solution to form a second solution; heating the second solution to a second temperature above 140° C.; and keeping the second solution at the second temperature long enough for the semiconductor nanocrystals to be formed.

Yet another embodiment of the invention is directed to a method of making Cu₂S nanocrystals, comprising the steps of: mixing ammonium diethyldithiocarbamate with dodecanethiol and oleic acid to form a first solution; heating the first solution to a first temperature no higher than 140° C.; injecting a suspension of copper (II) acetylacetonate and oleic acid into the first solution to form a second solution; heating the second solution to a second temperature above 140° C.; and keeping the second solution at the second temperature long enough for the Cu₂S nanocrystals to be formed.

These and other embodiments of the invention are described in further detail below.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic diagram of components in a photovoltaic or solar cell device according to an embodiment of the invention.

FIG. 2 is a plot of absorbance as a function of wavelength over the UV-Visible light range for a device at various stages of fabrication. The thin black curve (a) is for an ITO-coated glass substrate. The dotted curve (b) is for an ITO substrate with a PEDOT:PSS layer. The dashed curve (c) is for an ITO substrate with PEDOT:PSS and Cu₂S layers. The thick black curve (d) is for an ITO substrate with PEDOT:PSS, Cu₂S, and CdS layers. The inset is an AFM image of the final device shown in (d).

FIGS. 3a-3d show graphs showing a variety of electrical measurements made from Cu₂S—CdS nanocrystal photovoltaic devices, according to embodiments of the invention.

FIG. 4 shows a graph illustrating current density-voltage characteristics for a Cu₂S—CdS nanocrystal photovoltaic device on a flexible plastic substrate under various conditions. The dotted curve is for a device under zero illumination. The dashed curve is for a device under standard illumination on a flat plastic substrate and shows a 1.604% power conversion efficiency. The solid curve shows the current density voltage characteristic for the cell after it is bent to a curvature of 105° and then released to become flat again and shows a 1.472% power conversion efficiency. The inset is a photograph of a bent Cu₂S—CdS nanocrystal plastic solar cell.

FIG. 5a is an x-ray diffraction (XRD) pattern of Cu₂S nanocrystals as fabricated according to an embodiment of the invention. FIG. 5b is a transmission electron microscope (TEM) image of Cu₂S nanocrystals showing they have an average diameter of approximately 5.4 nm. The scale bar is 10 nm. The inset in the upper corner is a high resolution TEM image of a Cu₂S nanocrystal, showing that it has a single crystal hexagonal faceted structure. The scale bar is 1 nm. The inset in the lower corner is a two-dimensional Fourier transform (2DFT) of the image showing the [1 2̅1 3̅] zone axis of Cu₂S. FIG. 5c is a UV-Visible absorption spectrum of Cu₂S nanocrystals showing wide absorption up to approximately 1000 nm. The inset is a photoluminescence (PL) spectrum that shows a single peak centered at 985 nm, corresponding to a bandgap of 1.26 eV.

FIG. 6 shows the steps in fabrication and characterization of a Cu₂S—CdS nanocrystal photovoltaic device.

### DETAILED DESCRIPTION OF THE INVENTION

The aforementioned needs are satisfied by the embodiments of the present invention wherein a new approach to the colloidal synthesis of nanocrystals such as chalcocite (Cu₂S) has been discovered, and this material has been successfully deployed in a working photovoltaic device.

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. To the contrary, it is intended to cover alternatives, modifications, and equivalents as may be included within the scope of the appended claims. In the following description, numerous specific details are set forth in order to provide a thorough understanding embodiments of the present invention. Embodiments of the present invention may be practiced without some or all of these specific details. In other instances, well known process operations have not been described in detail in order not to unnecessarily obscure the present invention.

The term “non-sintered” is used herein to mean that there has been no heat treatment that would cause particles to sinter together. In general, heat treatments that cause sintering are around 200-300° C. or higher. In one embodiment of the invention, the term “non-sintered” can be interpreted as meaning that there has been no heat treatment at a temperature at or higher than about 250° C. In some embodiments, the term “non-sintered” can be interpreted as meaning that there has been no heat treatment at a temperature higher than about 200° C. In other embodiments, the term “non-sintered” can be interpreted as meaning that there has been no heat treatment at a temperature higher that about 150° C.

The term “flexible” is used herein in regard to a substrate to mean that the substrate can conform to a desired shape and bend or flex during its use without breaking.

The term “transparent” can be used herein in regard to a substrate to mean permitting light to come through without distortions so that objects on the other side can be seen clearly. The role of a transparent conductor in these devices is to deliver or collect electrons from the active part of the device while at the same time allowing photons to pass through relatively unimpeded. Transparent conductors allow energy (radiation) to pass in the following three energy spectrum: the near infrared (700 nm to 1400 nm), visible (400 nm to 700 nm), and ultraviolet (200 nm to 400 nm).

The term “electronically active” is used herein in regard to nanocrystal layers to mean that electrons and/or holes can transfer within and pass through the layers. Examples of such interactions include, but are not limited to, coulomb interactions, charge transfer, formation of a depletion region, and space charge interactions.

Small bandgap semiconductor nanocrystals have been used to make photovoltaic devices. The nanocrystal devices share all of the primary advantages of organic photovoltaic devices in their compatibility with solution process ability. Yet, the nanocrystal devices have shown even higher carrier mobility and less sensitivity to photo-oxidation than the organic devices.

In embodiments of the invention, a solution-phase synthesis approach has been used to make nanocrystals such as monodispersed hexagonal copper (I) sulfide (Cu₂S) chalcocite nanocrystals at low temperature and atmospheric pressure. The Cu₂S nanocrystals have been used with cadmium sulfide (CdS) nanorods to fabricate solar cells on both glass and plastic substrates. The solar cells have a power conversion efficiency exceeding 1.6% (e.g., at A.M. 1.5 global illumination) and have shown stability over a period of at least 120 days without obvious degradation in performance. These results indicate that such a device offers a promising solution for low-cost power conversion.

In one embodiment of the invention, an electronically active layered structure has a first layer of a first kind of nanocrystal and a second layer of a second kind of nanocrystal. The layers interact with each other electronically. Examples of such interactions include, but are not limited to, coulomb interaction, charge transfer, formation of a depletion region, and space charge interactions. In one arrangement, each layer contains only one kind of nanocrystal, and each layer may contain only nanocrystals bound together. In another arrangement, the nanocrystals have organic molecules associated with them. For example, in some embodiments of the invention, in the first and second layers may include a polymeric binder along with the nanocrystals. Suitable polymer binders may include blends or polymers, and they may comprise conjugated and/or non-conjugated polymers. In yet another arrangement, each layer can contain additional material as long as the additional material does not have a significant effect on the electronic properties of the layered structure.

In some embodiments of the invention, none of the materials used in the layered structure undergoes a sintering treatment in the fabrication of the layered structure. That is, the materials and the layered structure are non-sintered. During fabrication, the layered structure can be exposed to temperatures no higher than 350° C. In another arrangement, during fabrication, the layered structure is exposed to temperatures no higher than 300° C. In another arrangement, during fabrication, the layered structure is exposed to temperatures no higher than 250° C. In another arrangement, during fabrication, the layered structure is exposed to temperatures no higher than 200° C. In another arrangement, during fabrication, the layered structure is exposed to temperatures no higher than 150° C. In another arrangement, during fabrication, the layered structure is exposed to temperatures no higher than 100° C.

In one embodiment of the invention, the first layer comprises a first type of nanocrystal such as Cu₂S nanocrystals and the second layer comprises a second type of nanocrystals such as CdS nanocrystals. The CdS nanocrystals can be in the form of nanorods either with or without branching. In some embodiments, additional layers of non-sintered nanocrystals, either electronically active or not, can be added to the original Cu₂S/CdS bilayer. Examples of other bilayers that can be used include, but are not limited to, Cu₂S/CdS, CdSe/CdTe, ZnO/ZnS, CdS/CdTe, and CuO/ZnO.

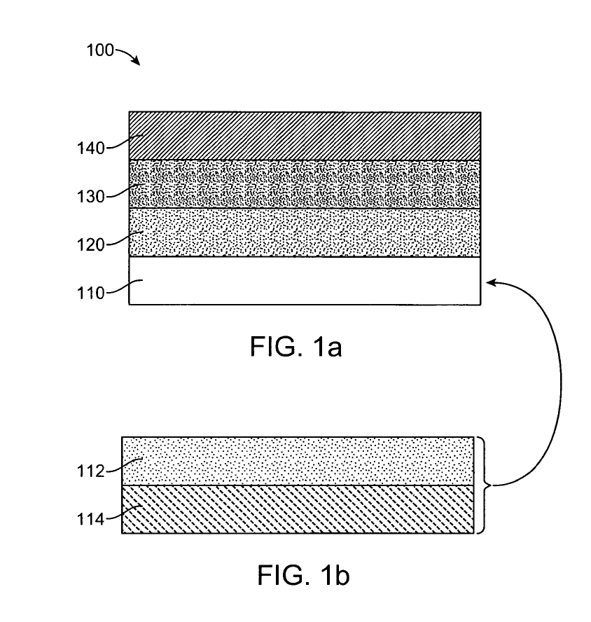

In another embodiment of the invention, the bilayer described above can be used to make a solar cell device. As shown in FIG. 1a, the device 100 has a substrate 110 adjacent the Cu₂S 120 nanocrystal layer. The substrate 100 itself is transparent and can be made of one layer or multiple layers, as long as the layer immediately adjacent the Cu₂S layer 120 is conducting. It is useful if the transparent conducting material adjacent the Cu₂S layer 120 has a work function between about −4.0 eV and −6.0 eV. Examples of such transparent conducting materials include, but are not limited to, any transparent conducting oxide (TCO), such as indium tin oxide (ITO), tin oxide, zinc oxide, and cadmium tin oxide. Other materials that can be used include carbon nanotubes or metal wire arrays, which can be arranged sparsely so that they are conducting enough while also being essentially transparent. Examples of substrate layers onto which the conducting layer can be formed include glass and plastic. The substrate 100 can be rigid or flexible.

An example of a bilayer substrate 110 is show in FIG. 1b, wherein the layer 112 adjacent the Cu₂S layer 120 is ITO and the ITO layer 112 is supported by a glass or other base 112. The base 112 may or may not be conducting. The solar cell device has a CdS layer 130 adjacent the Cu₂S layer 120 and a conducting layer 140 adjacent the CdS layer 130. The conducting layer 140 can be made of metal. Examples of suitable materials for to conducting layer 140 include, but are not limited to, aluminum, iron, gold, nickel, and calcium.

The various layers shown in the device 100 may have any suitable thicknesses. In some embodiments, each layer may have a thickness less than about 100 or 10 microns, or even less than 1 micron.

In one embodiment of the invention, the solar cell device is prepared using a low temperature (≦150° C.) solution process to form a heterojunction between the layer 120 of Cu₂S nanocrystals and the layer 130 of CdS nanocrystals or nanorods. In one arrangement the Cu₂S layer 120 has a thickness between about 100 nm and 500 nm. In another arrangement the Cu₂S layer 120 has a thickness between about 200 nm and 400 nm. In another arrangement the Cu₂S layer 120 has a thickness between about 250 nm and 350 nm. In another arrangement the Cu₂S layer 120 has a thickness of about 300 nm. In one arrangement the CdS layer 130 has a thickness between about 50 nm and 1000 nm. In another arrangement the CdS layer 130 has a thickness between about 75 nm and 300 nm. In another arrangement the CdS layer 130 has a thickness between about 100 nm and 200 nm.

In one embodiment of the invention, the Cu₂S nanocrystals comprise a coating and the coating may have dodecanethiol (or other alkylthiol) on their surfaces. The dodecanethiol is on the outer surface of the nanocrystals. In one arrangement, the dodecanethiol covers the entire surface of some or all of the nanocrystals. In another arrangement, the dodecanethiol only partially covers the surface of the nanocrystals. The dodecanethiol layer can at least partially passivate, or attach to defects in, the nanocrystals. This may cause the Cu₂S nanocrystals to be more stable in air than has been reported for Cu₂S nanocrystals made by other methods.

In one embodiment of the invention, the CdS nanocrystals have a coating comprising oleylamine and/or pyridine on their surfaces. The oleylamine and/or pyridine is on the outer surface of the nanocrystals. In one arrangement, the oleylamine and/or pyridine covers the entire surface of some or all the nanocrystals. In another arrangement, the oleylamine and/or pyridine only partially covers the surface of the nanocrystals. The oleylamine and/or pyridine layer can at least partially passivate, or attach to defects in, the nanocrystals.

In another embodiment of the invention, a solar cell device has a structure that can be described with reference to FIG. 1. The device 100 has a flexible substrate 110, a layer 120 comprising first inorganic nanocrystals adjacent the substrate, a layer 130 comprising second inorganic nanocrystals adjacent the layer 120, and a conducting layer 140 adjacent the layer 130. Examples of first inorganic nanocrystals include, but are not limited to, copper sulfide (Cu₂S), cadmium telluride (CdTe), cadmium selenide (CdSe), zinc oxide (ZnO), cadmium sulfide (CdS), and copper oxide. Examples of second inorganic nanocrystals include, but are not limited to, CdS, CdTe, zinc sulfide (ZnS), and ZnO. Examples of first/second nanocrystal pairs include, but are not limited to, Cu₂S/CdS, CdSe/CdTe, ZnO/ZnS, CdS/CdTe, and CuO/ZnO. In some embodiments of the invention, the first and/or second nanocrystals may comprise III-V and II-VI type semiconductors. The solar cell device 100 is non-sintered, i.e., there is no sintering step used in the fabrication of the device from the nanocrystals and the other materials.

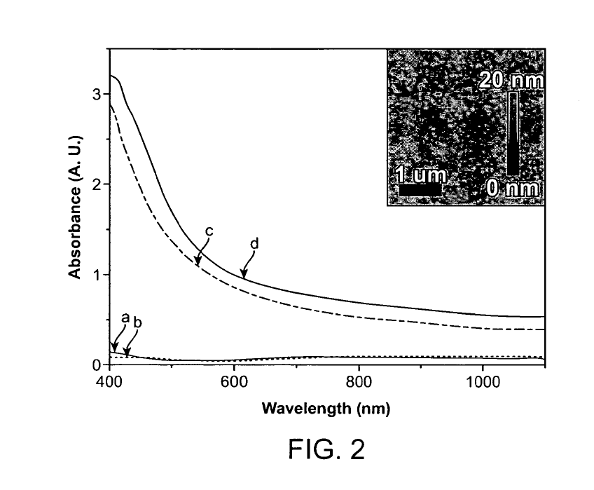

FIG. 2 is a plot of absorbance as a function of wavelength over the UV-Visible light range for an exemplary photovoltaic device at various stages of fabrication, all of which occur at temperatures less than about 150° C. The critical heterojunction is formed between a layer of Cu₂S nanocrystals and a layer of CdS nanorods. The thin black curve (a) is for an ITO-coated glass substrate. The dotted curve (b) is for an ITO substrate with a PEDOT:PSS (poly(3,4-ethylenedioxythiophene) doped with poly(styrene sulfonic acid)) layer. The dashed curve (c) is for an ITO substrate with PEDOT:PSS and Cu₂S layers. The thick black curve (d) is for an ITO substrate with PEDOT:PSS, Cu₂S, and CdS layers. In this exemplary embodiment, the thickness of the Cu₂S nanocrystal layer and the CdS nanorod layer are measured to be around 300 nm and 100 nm, respectively. The inset is an AFM image of the final device (d), which shows the total film surface roughness to be less than about 4 nm. The average optical density is approximately 1.1.

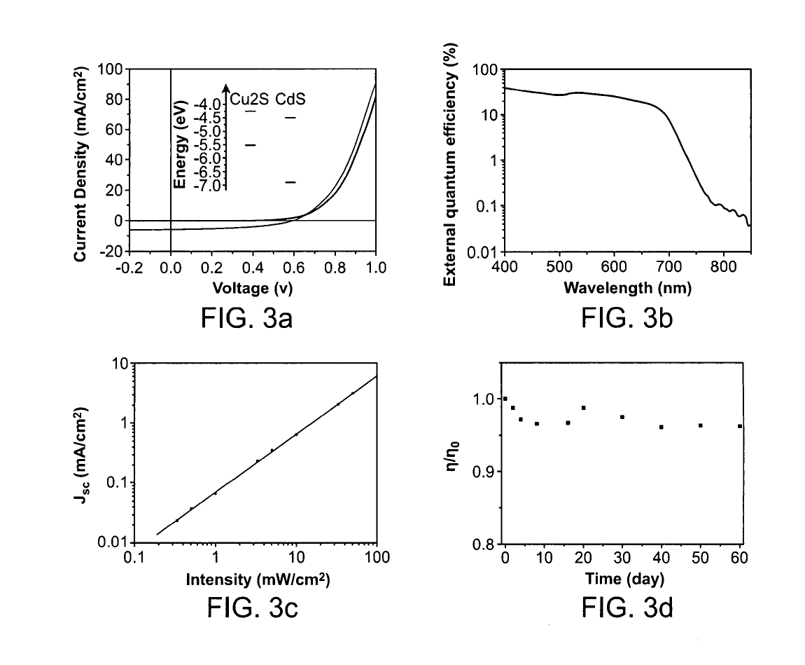

The series of graphs in FIG. 3 show electrical measurements of Cu₂S—CdS nanocrystal photovoltaic devices according to an embodiment of the invention. In FIG. 3a, current density-voltage characteristics of an as-made photovoltaic device under zero illumination (black curve) show typical rectification behavior. Under standard illumination (irradiance 100 mW/cm², temperature 25° C., AM=1.5G), the device shows a open circuit voltage (V_{oc}) of 0.6 V and a short circuit current density (J_{sc}) of 5.63 mA/cm², as shown by the grey curve in FIG. 3a, corresponding to a power conversion efficiency (η) of 1.600% with a fill factor (FF) of 0.474. The diagram in the inset of FIG. 3a shows the Type II band alignment of Cu₂S—CdS. FIG. 3b is a spectral response measurement that shows external quantum efficiencies (EQE) approaching 40%. The external quantum efficiency data with the true AM1.5G solar emission spectrum match well with the short-circuit currents obtained under the simulated AM1.5G illumination as shown in FIG. 3a.

V_{oc} for the Cu₂S—CdS nanocrystal-based solar cells disclosed herein is better than the best values, 0.54 V, previously reported for conventional Cu₂S—CdS thin film solar cells. Without wishing to be bound to any particular theory, this result may be due to the planar junction between Cu₂S and CdS nanocrystals that is created during sequential spin coating (total roughness˜4 nm). The spin coating process may help to avoid the textured junction that is created when conventional “wet” or “dry” processes are used. In the wet process CdS is dipped into a CuCl aqueous solution. In the dry process Cu₂S is formed by evaporating CuCl onto CdS followed by annealing at temperatures between 250° C. and 500° C. It may also be that dodecanethiol residues on the nanocrystals fabricated by the process described herein, contribute in the passivation of trap states.

Although spin coating is an exemplary method for forming the layers with the first and second nanocrystals types, it is understood that other types of coating processes can be used in other embodiments of the invention. For example, other suitable wet coating processing techniques include roller coating, doctor blade coating, etc.

Furthermore, the photovoltaic nanocrystal devices described herein have a distinct advantage over state-of-the-art all-inorganic nanocrystal photovoltaic devices. The CdS—Cu₂S devices of the present invention can be made repeatedly and reliably at low temperatures and atmospheric pressure, therefore using much less energy for fabrication than is used for devices that require high temperature (for example, temperatures greater than 200° C.) for annealing or sintering. In addition, the Cu₂S nanocrystals of these devices have been shown to be air stable. Previous attempts to use these nanocrystals in devices have not been successful because of instability in air.

Another feature of the devices of the present invention is that their I-V curves as measured in the light and in the dark intersect, as shown in FIG. 3a. Such behavior has also been observed in annealed CdS—Cu₂S thin film photovoltaic cells and is known as the “cross-over effect”. It is believed that this effect indicates the formation of a photoactive interfacial CdS layer due to copper diffusion into n-type CdS. The crossover in FIG. 3a is evidence that the same photovoltaic mechanism is at work in the nanocrystal solar cells described herein as has been observed in thin film devices. More specifically, it seems that electron-hole pairs are created in the Cu₂S layer by the absorption of photons with energy larger than the bandgap of Cu₂S. The electrons diffuse to the Cu₂S—CdS interface, where they pass into the CdS layer and either diffuse through the CdS layer by the electric field in the space-charge region or are trapped by the interface states and recombine with holes from the Cu₂S layer at the interface. This interfacial CdS layer also results in the decay of EQE between 700 nm to 800 nm in the photoaction spectrum (FIG. 3b) because of its low transparency to the photoexcited electrons from the Cu₂S generated by long-wavelength light, which is also consistent with previous Cu₂S—CdS thin film solar cell studies.

Photovoltaic parameters have also been determined as a function of illumination intensity (I). FIG. 3c is a plot of short circuit current density (J_{sc}) as a function of illumination intensity (I) (black dots) showing a near-linear relationship, as indicated by the line drawn through the dots. The grey line can be described by J_{sc}∝Iⁿ, with n=0.97. The near-linear relationship implies that only minor charge-carrier recombination is occurring in these photovoltaic devices. Furthermore, FIG. 3d shows that during measurements over a 120 day period, the device (under encapsulation in an argon atmosphere) has nearly constant performance, thus demonstrating excellent stability of the nanocrystal photovoltaic elements.

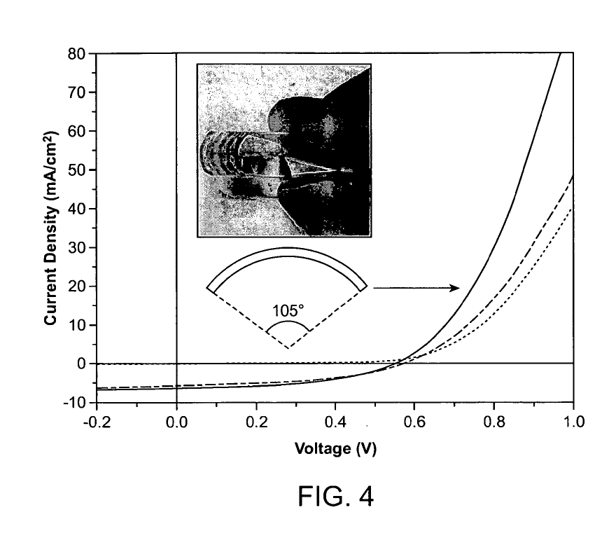

In another embodiment of the invention, functional nanocrystal solar cells fabricated using a simple low temperature solution process can be made on substrates that heretofore have not been possible because of the need for high temperature processing. For example, the nanocrystals can be fabricated onto plastic substrates, which offer many attractive properties, including flexibility, light weight, shock resistance, softness, and transparency. As a demonstration, Cu₂S—CdS solar cells have been fabricated onto an ITO-coated plastic substrate. A photograph of such a device being bent is shown in FIG. 4 in the upper inset.

FIG. 4 shows current density-voltage characteristics for the Cu₂S—CdS nanocrystal photovoltaic device on the flexible plastic substrate under various conditions. The dotted curve is for a device under zero illumination. The dashed curve is for the device under standard illumination as the flexible plastic substrate is held flat and shows a 1.604% power conversion efficiency. The solid curve shows the current density voltage characteristic for the device after it has been bent to a curvature of 105° and then released to become flat again and shows a 1.472% power conversion efficiency. This efficiency change from the unbent device is small (˜8%), especially given the large stress on the device during the bending. This is an indication of the robust nature of the nanocrystal/plastic solar cells. Such cells could be used to supply power to devices where flexibility is needed, such as in flexible handheld consumer electronics.

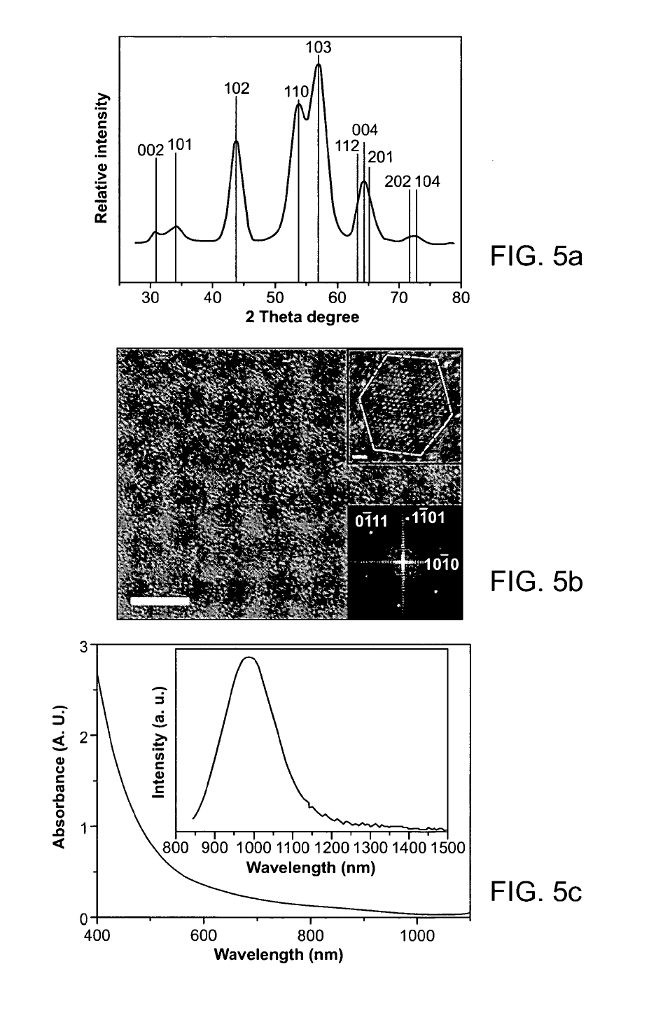

FIG. 5 shows the structural characterization of Cu₂S nanocrystals fabricated according to an embodiment of the invention. FIG. 5a shows an x-ray diffraction pattern XRD from Cu₂S nanocrystals. The pattern can be indexed as hexagonal chalcocite Cu₂S (JCPDS 026-1116, vertical lines). FIG. 5b is a low-resolution TEM image of Cu₂S nanocrystals, showing monodispersed nanocrystals with an average size of 5.4±0.4 nm. The scale bar is 10 nm. The inset in the upper right is a high-resolution TEM image of a Cu₂S nanocrystal, confirming that the observed nanocrystals are Cu₂S and showing several important features. The TEM data demonstrate clearly that the Cu₂S nanocrystals are single crystal structures. The Cu₂S nanocrystals have a well-defined hexagonal-faceted structure (dashed line, upper inset, FIG. 5b). The scale bar is 1 nm. The inset in the lower right shows reciprocal lattice peaks, which were obtained from two-dimensional Fourier transforms (2DFT) of the lattice-resolved image (FIG. 5b upper inset) and can be indexed to the hexagonal structure of Cu₂S with the zone axis along the [1 2̅1 3̅] direction.

Other embodiments of the invention are directed to methods for making semiconductor nanocrystals, each semiconductor nanocrystal comprising a first element (e.g., Cu) and a second element (e.g., S). The method comprises mixing a first precursor (e.g., ammonium diethyldithiocarbamate) comprising the second element and an organic solvent to form a first solution, heating the first solution to a first temperature no higher than 140° C., injecting a suspension comprising a second precursor (e.g., copper (II) acetylacetonate) comprising the first element into the first solution to form a second solution, heating the second solution to a second temperature above 140° C., and keeping the second solution at the second temperature long enough for the semiconductor nanocrystals to be formed.

The first element may be a transition metal such as Zn, Ag, Cu, etc. The precursor which contains the first element may be derived from a salt of that transition metal. For example, a suitable precursor any copper salt, including a copper salt containing inorganic and/or organic species, with a copper valence to be 1+ or 2+ would be suitable in embodiments of the invention. For example, copper (II) acetylacetonate, copper (I) chloride, copper (I) acetate, and copper (II) acetate are suitable precursors.

The second element may be, without limitation, an element from Group VI of the periodic table including O, S, and Se. The precursor which contains the second element may be a chelating agent such as a thiocarbamate (e.g., ammonium diethyldithiocarbamate) or a surfactant such as an alkylthiol (e.g., dodecanethiol) or the alkylamine solution comprising the second element (e. g. sulfur dissolved in oleylamine).

The above described organic solvent may comprise any suitable material. The solvent may comprise surfactants such as alkylthiols, fatty acids, amines, etc.

In one specific embodiment of the invention, Cu₂S nanocrystals have been prepared by using a novel colloidal synthesis approach that involves an injection reaction between a second precursor such as copper (II) acetylacetonate and a first precursor such as ammonium diethyldithiocarbamate in a mixed solvent of dodecanethiol and oleic acid. The Cu₂S nanocrystals made by this solution-phase synthesis approach are pure, single-phase, monodispersed hexagonal copper (I) sulfide (Cu₂S) chalcocite.

In one embodiment, Cu₂S nanocrystals are synthesized by mixing ammonium diethyldithiocarbamate with dodecanethiol and oleic acid. The solution is heated up to a temperature no higher than 140° C., followed by quick injection of a suspension of copper (II) acetylacetonate and oleic acid. Then, the solution is quickly heated up to a temperature above 140° C. and is kept at the temperature long enough for Cu₂S nanocrystals to be formed. The Cu₂S nanocrystals are then precipitated out from the solution and cleaned using organic solvents, as is well known in the art of nanocrystal synthesis.

In a specific example, Cu₂S nanocrystals are synthesized as follows: 1.25 mmol of ammonium diethyldithiocarbamate is mixed with 10 mL dodecanethiol and 17 mL oleic acid in a three-neck flask. The solution is heated up to 110° C. under Argon (Ar) flow followed by quick injection of a suspension composed of 1 mmol copper (II) acetylacetonate and 3 mL oleic acid. Then, the solution is quickly heated up to 180° C. and kept at the temperature for 10-20 minutes.

The cleaning of the nanocrystals can involve multiple steps performed in a glovebox with Ar protection. All the solvents used are anhydrous to avoid any possible oxidation. Right after the reaction that synthesized the nanocrystals, the solution containing Cu₂S nanocrystals is allowed to cool down to approximately 120° C. before being taken out of the flask for centrifuging at approximately 4600 rpm for approximately 10 minutes. The supernatant is discarded and the precipitate is first fully dissolved in approximately 4 g of toluene and then precipitated out by adding 11 g of isopropanol followed by centrifuging at 4600 rpm for 10 minutes. This procedure can be repeated up to three times or more to clean away the residue of dodecanethiol and oleic acid. The synthesis of CdS nanorods is conducted in a manner similar to that described above. The details can be found in J. Phys. Chem. C 111, 2447-2458 (2007), “Shape control of CdS nanocrystals in one-pot synthesis” by Yong, K., Sahoo, Y., Swihart, M. T., Prasad, P. N., which is included by reference herein.

The optical properties of Cu₂S nanocrystals were studied by UV-Visible (UV-Vis) absorption spectroscopy and photoluminescence (PL) to further assess their quality. A representative UV-Vis spectrum (FIG. 5c) recorded from Cu₂S nanocrystals dispersed in chloroform at room temperature shows wide absorption up to approximately 1000 nm. The inset shows the photoluminescence (PL) spectrum indicating a single peak centered at 985 nm, corresponding to a bandgap of 1.26 eV. This is similar to reported bulk bandgap values of 1.21 eV, with a full-width at half maximum (FWHM) of 148 nm.

In an exemplary embodiment, once the Cu₂S and CdS nanocrystals are synthesized, they are each dissolved separately into 15 mL pyridine and kept at 120° C. for at least one day, allowing for comprehensive ligand exchange. Then, the nanocrystals are precipitated out using an appropriate amount of hexane. The Cu₂S nanocrystals and the CdS nanorods are dissolved separately into appropriate amounts of chloroform (CHCl₃) and then passed through a 0.4 μm Teflon filter to make stock solutions for bilayer or photovoltaic device fabrication.

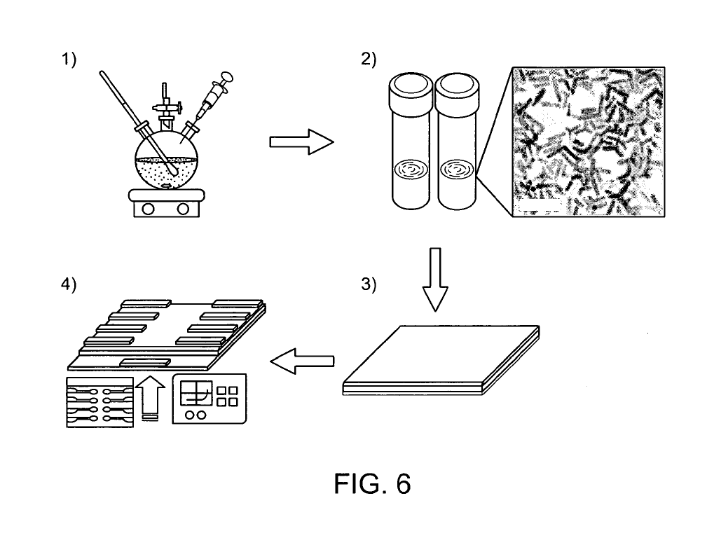

In an exemplary embodiment, a Cu₂S/CdS nanocrystal bilayer is made according to steps 1-3 as outlined in FIG. 6. In step 1, Cu₂S nanocrystals and CdS nanorods are made using solution-phase synthesis. In step 2, Cu₂S nanocrystals and CdS nanorods are cleaned to make stock solutions for bilayer fabrication. The inset is a TEM image of the CdS nanorods, showing that some are simple rods and some are branched. The scale bar is 50 nm. In step 3, Poly(3,4-ethylenedioxythiophene) poly(styrenesulfonate) (PEDOT:PSS), Cu₂S nanocrystals and CdS nanorods are sequentially spin-cast onto a substrate. Any suitable spin speeds can be used in embodiments of the invention (e.g., less than about 6000 rpm).

In another exemplary embodiment, a Cu₂S/CdS nanocrystal photovoltaic device is made according to steps 1-4 as outlined in FIG. 6. In step 1, Cu₂S nanocrystals and CdS nanorods are made using solution-phase synthesis. In step 2, Cu₂S nanocrystals and CdS nanorods are cleaned to make stock solutions for bilayer fabrication. The inset is a TEM image of the CdS nanorods, showing that some are simple rods and some are branched. The scale bar is 50 nm. In step 3, PEDOT:PSS, Cu₂S nanocrystals and CdS nanorods are spin-cast sequentially onto a substrate. In step 4, conducting electrodes are deposited onto the bilayer structure. Various methods of depositing conducting materials, such as metals, onto such a bilayer structure are well know in the art: thermal evaporation, sputtering, applying metal paint, etc.

Glass substrates coated with 150 nm ITO (Thin Film Devices Inc., resistivity 20 ohms/sq) are cleaned by ultrasonication for approximately 30 minutes in an even mixture of acetone and isopropanol and then deionized water, respectively. The substrates are then dried under a stream of nitrogen followed by oxygen plasma cleaning for 15 minutes at 0.2 torr. A filtered dispersion of PEDOT:PSS in water (Baytron-PH) was immediately spin-cast at 4000 rpm for one minute and then baked for 30 minutes at 120° C. After cooling down, nanocrystal films are spin-cast at 600 rpm onto the substrates. To create bilayer structures, Cu₂S films are spin-cast first and then heated for 10 minutes at 150° C. to remove excess solvent and allow for spin-casting of the second films of CdS. Then, the substrates are annealed again for about 5 to 10 minutes at 150° C. After that, the substrates are held at approximately 10⁻⁷ torr for up to 12 hours, after which 200 nm of conducting electrode material, e.g., aluminum are deposited by thermal evaporation through a shadow mask, resulting in individual devices with 0.04 cm² nominal areas. After evaporation, a rapid thermal annealing is performed on the devices at 150° C. for about 30 to 60 seconds. The procedure of fabricating photovoltaic device on a plastic substrate is the same as described above except that ITO-coated plastic substrates (e.g., OC™50 (50 ohms per square ITO) made by CP Films, Inc. of Martinsville, Va.) are used instead of the regular ITO-coated glass substrates. In addition, the oxygen plasma cleaning time is reduced to 3.5 minutes.

In summary, monodispersed single crystal Cu₂S nanocrystals can be synthesized in a solution-phase reaction. The incorporation of the Cu₂S nanocrystals into photovoltaic devices, whose active region is composed of nanocrystals, yields a power conversion efficiency exceeding 1.6%. Such a device can be made at extremely low cost and with high throughput. In the past, attempts at using Cu₂S in devices have failed because of the instability of Cu₂S in air. The devices described herein are completely air stable. Furthermore, the devices do not use a lot of energy in fabrication as there is no annealing or sintering step—a distinct advantage over other bulk thin film photovoltaics, as well as other all inorganic photovoltaic material systems. The low temperature solution-phase process used to fabricate these nanocrystal solar cell devices opens up the possibility of a promising technique for low-cost power conversion on plastic substrates for future flexible electronics.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

What is claimed is:

1. A non-sintered structure comprising:
a first non-sintered nanocrystal layer; and
a second non-sintered nanocrystal layer wherein the first layer and the second layer are configured to interact electronically.

2. The device of claim 1 wherein the first layer comprises Cu₂S.

3. The device of claim 1 wherein the second layer comprises CdS.

4. The device of claim 1, further comprising at least one additional layer of non-sintered electronically active nanocrystals.

5. A solar cell device, comprising:
a substrate comprising a first conducting layer;
a Cu₂S nanocrystal layer adjacent the first conducting layer of the substrate;
a CdS nanocrystal layer adjacent the Cu₂S nanocrystal layer; and
a second conducting layer adjacent the CdS nanocrystal layer.

6. The device of claim 5 wherein the substrate comprises at least two layers, a transparent first conducting layer adjacent the Cu₂S nanocrystal layer and a transparent base layer.

7. The device of claim 6 wherein the transparent first conducting layer comprises a material that has a work function between about −4.0 eV and −6.0 eV.

8. The device of claim 7 wherein the transparent first conducting layer is selected from the group consisting of transparent conducting oxides, indium tin oxide, tin oxide, zinc oxide, cadmium tin oxide, carbon nanotubes or metal wire arrays.

9. The device of claim 5 wherein the substrate is flexible.

10. The device of claim 5 wherein the second conducting layer adjacent the CdS nanocrystal layer is selected from the group consisting of metals, metalloids, transition elements, and carbon based conductive nanostructures.

11. The device of claim 5 wherein the Cu₂S nanocrystals have an outer surface that comprise at least a partial layer of dodecanethiol.

12. The device of claim 11 wherein the dodecanethiol layer at least partially passivates the Cu₂S nanocrystals.

13. The device of claim 5 wherein the CdS nanocrystals have an outer surface that comprise at least a partial layer of oleylamine and/or pyridine.

14. The device of claim 13 wherein the oleylamine and/or pyridine layer at least partially passivates the CdS nanocrystals.

15. A solar cell device, comprising:
a flexible substrate having at least one conducting surface;
a layer of first inorganic nanocrystals adjacent the conducting surface of the substrate;
a layer of second inorganic nanocrystals adjacent the first layer; and
a conducting layer adjacent the second layer.

16. The device of claim 15 wherein first/second nanocrystal pairs are selected from the group consisting of Cu₂S/CdS, CdSe/CdTe, ZnO/ZnS, CdS/CdTe, and CuO/ZnO.

17. A method comprising:
forming a first non-sintered nanocrystal layer; and
forming a second non-sintered nanocrystal layer wherein the first layer and the second layer are configured to interact electronically.

18. The method of claim 17 wherein the first layer comprises Cu₂S and the second layer comprises CdS.

19. The method of claim 17 further comprising, forming the first non-sintered nanocrystal layer and the second non-sintered nanocrystal layer on a substrate, and then subsequently forming a solar cell device.

20. A method for making semiconductor nanocrystals, each semiconductor nanocrystal comprising a first element and a second element, the method comprising:
mixing a first precursor comprising the second element and an organic solvent to form a first solution;
heating the first solution to a first temperature no higher than about 140° C.;
injecting a suspension comprising a second precursor comprising the first element into the first solution to form a second solution;
heating the second solution to a second temperature above about 140° C.; and
keeping the second solution at the second temperature long enough for the semiconductor nanocrystals to be formed.

21. The method of claim 20 wherein the first precursor comprising the first element is selected from the group consisting of a thiocarbamate, an alkythiol, and combinations thereof, and wherein the organic solvent comprises an organic surfactant.

22. The method of claim 20 wherein the second precursor comprises a metal salt.

23. The method of claim 20 wherein the plurality of nanoparticles comprise monodisperse Cu₂S nanocrystals.

24. A plurality of nanocrystals made by the method of claim 20.

25. A plurality of substantially pure monodisperse nanocrystals comprising Cu₂S.

26. A method of making Cu₂S nanocrystals, comprising the steps of:
mixing ammonium diethyldithiocarbamate with dodecanethiol and oleic acid to faun a first solution;
heating the first solution to a first temperature no higher than 140° C.;
injecting a suspension of copper (II) acetylacetonate and oleic acid into the first solution to form a second solution;
heating the second solution to a second temperature above 140° C.; and
keeping the second solution at the second temperature long enough for the Cu₂S nanocrystals to be formed.
